(19) United States
(12) Patent Application Publication
(10) Pub. No.: US 2024/0104447 A1
(43) Pub. Date: Mar. 28, 2024

(54) SYSTEM AND METHOD FOR DETERMINING AN OPTIMAL SUBMARINE PATH FOR AN INFRASTRUCTURE LINK IN TWO LOCATIONS OF A TARGET REGION

(71) Applicant: City University of Hong Kong, Hong Kong (HK)

(72) Inventors: Xinyu WANG, Yongji (CN); Zengfu WANG, Hong Kong (HK); Tianjiao WANG, Hong Kong (HK); Moshe ZUKERMAN, Hong Kong (HK)

(21) Appl. No.: 18/315,517

(22) Filed: May 11, 2023

Related U.S. Application Data
(60) Provisional application No. 63/409,230, filed on Sep. 23, 2022.

(51) Int. Cl. G06Q 10/047; G06Q 10/0635; G06Q 30/0283

(52) U.S. Cl. CPC G06Q 10/047; G06Q 10/0635; G06Q 30/0283

(57) ABSTRACT

The invention provides a method of determining an optimal submarine cable path between a starting point and an end point in a target region of Earth's surface. The method includes building a triangulated two-dimensional (2D) manifold model of the target region, creating an objective function based on risk and cost, and minimizing the function to obtain a set of Pareto optimal solutions for deriving a Pareto front. Furthermore, the Pareto front is further optimized by taking into account terrain slope, marine protected areas, and volcanic safety constraints. Finally, an optimal submarine cable path is selected based on the optimized Pareto front and a given condition.

### CROSS-REFERENCES WITH RELATED DOCUMENTS

The present application claims priority to U.S. Patent Application No. 63/409,230 filed Sep. 23, 2022; the disclosure of which is incorporated herein by reference in its entirety.

### FIELD OF THE INVENTION

The present invention generally relates to techniques of routing submarine cables. More particularly, the present invention relates to techniques of determining an optimal submarine cable path in a target region of the Earth's surface, taking into account terrain slope, marine protected areas, and volcanic safety constraints.

### BACKGROUND OF THE INVENTION

Long-haul submarine communication cable system using low-loss optical fiber has been playing an essential role in international data transmission due to its reliability, economic, and large-capacity characteristics. Nowadays, submarine communications cables (hereinafter referred to as submarine cables) are used to connect the world and carry 99% of the global data traffic. The types of users of submarine cables are extensive. Telecom operators, content providers, multinational corporations, governments, and research institutes all rely heavily on submarine cables to transmit data worldwide. Submarine cables significantly reduce communication times between continents and are the cornerstone of globalization and global communications.

Submarine cables are vulnerable to various natural disasters and man-made accidents, such as earthquakes, volcanic eruptions, fishing, anchoring, and ocean dumping, leading to more than 100 cable failures per year on average. The interruption of a submarine cable may lead to economic losses and dire social consequences.

The industry currently relies on experts' experience in designing cost-effective and reliable submarine cable systems. In particular, planners use available data on the target areas, from maps, aerial photographs, charts, and satellite gravity bathymetric data, to draw initial paths that connect a starting point to an end point with the help of MakaiPlan™ software. Then, a preliminary survey is conducted for a given path to verify its feasibility and rationality. Finally, the planners determine the path route after carefully studying all the relevant data along the initial path with comparison to the alternatives. This approach relies on the subjective judgments of planners.

Since a planner cannot always consider all available alternatives given the time and resource limitations, this approach cannot provide a near-optimal path nor consider all of the various factors that may affect the cost and resilience of the submarine cables. Therefore, it is necessary to develop a more effective method for planning submarine cable paths that addresses the aforesaid shortcomings.

### SUMMARY OF THE INVENTION

In accordance with a first aspect of the present invention, a method for determining an optimal submarine cable path between a starting point and an end point in a target region of Earth's surface is provided, which includes the following steps. Step S10: a triangulated two-dimensional manifold model of the target region is built according to the geographic information of the target region. Step S20: an objective function at least including a risk function and a cost function with respect to the model is established. Step S30: the objective function with different weight factors is minimized to obtain a set of Pareto optimal solutions in response to the weight factors, respectively, so as to derive a Pareto front. Step S40: the Pareto front is optimized by satisfying terrain slope and volcanic safety constraints, so as to obtain an optimized Pareto front. Step S50: one of optimized Pareto optimal solution of the optimized Pareto front is selected by using a given condition, so as to determine the optimal submarine cable path.

In accordance with one embodiment, the geographic terrain of the target region is modelled, such that each location point in the model is denoted by a three-dimensional (3D) coordinate.

In accordance with one embodiment, the cost function is at least determined by at least one of factors including length of the submarine cable, location of the submarine cable, and licensing requirements for security arrangements in specific areas where the submarine cable is to be laid. It should be noted that the cost associated with the cable length includes the cost of repeaters, which are installed every approximately fixed distance in the range of 45 to 90 km depending on the cable to eliminate the signal attenuation. The risk function is at least determined by a PGV data of the target region. The objective function is established by using the cost function and the risk function. And the objective function can be expressed as the following equation:

Z(p)=C(p)+wR(p);

wherein p represents a submarine cable path, Z(p) represents the objective function, C(p) represents the cost function, R(p) represents the risk function, and w represents the weight factor.

In accordance with one embodiment, the step of minimizing the objective function further includes applying a fast-marching method (FMM) to minimize the objective function with different weight factors to obtain a set of Pareto optimal solutions (a Pareto front).

In accordance with one embodiment, the step of applying the FMM further includes the following steps. Step S301: calculating an objective function value of each of points in the model with one of the weight factors. Step S302: the reciprocal of the objective function value for each of the points is taken for converting the minimization into an Eikonal equation. Step S303: applying the FMM to solve Eikonal equation. Step S304: calculating an arrival time from the end point to each of the points in the model iteratively until the end point is reached. Step S305: backtracking from the start point to the end point, and using the shortest arrival time of the points to generate one of the Pareto optimal solutions. Step S306: repeating step S301 to step S305 with the other weight factors to obtain the set of Pareto optimal solutions.

In accordance with one embodiment, after the step of obtaining the Pareto front, each of the optimized Pareto optimal solutions represents a corresponding potential optimal submarine cable path. The potential optimal submarine cable path satisfies the Terrence slope constraint, such that the potential optimal submarine cable path is located in a sub-region of the target region where the terrain slope does not exceed approximately 20 degrees.

In accordance with another embodiment, after the step of obtaining the Pareto front, each of the optimized Pareto optimal solutions represents a corresponding potential optimal submarine cable path. The potential optimal submarine cable path satisfies the volcanic safety constraint, such that the minimum distance between one of the volcanos and the nearest point of the potential submarine cable path is greater or equal to a volcanic safety distance of the corresponding volcano. The volcanic safety distance is determined by highest historical volcanic explosivity index (HEVI) of the corresponding volcano in the target region.

In accordance with one embodiment, after the step of obtaining the Pareto front, each of the optimized Pareto optimal solutions represents a corresponding potential optimal submarine cable path. The potential optimal submarine cable path satisfies the marine protected area constraint, such that the potential optimal submarine cable path is located in a sub-region of the target region beyond the marine protected areas of the target region. In other words, the marine protected areas and the submarine cable installation areas do not overlap with each other.

In accordance with one embodiment, the given condition includes a constant risk or a constant cost; and the geographic information of the target region comprises longitude, latitude, elevation, earthquake data, and volcano data of the target region.

In accordance with a second aspect of the present invention, a system for determining an optimal submarine cable path between a starting point and an end point in a target region of Earth's surface is provided. The system includes at least one or more processors and an electronic display. The one or more processors is arranged to execute the aforesaid method. The electronic display is arranged to display the determined optimal submarine cable path.

Based on above, the embodiments of the present invention provide cost-effective and reliable path planning methods and systems for determining optimal submarine cable paths that minimize breaking risk and cost. The methods and systems take into consideration of the terrain slope and volcanic safety constraints in obtaining an optimized Pareto front. An ordinarily skilled person in the art can appreciate that different optimized Pareto optimal solutions of the optimized Pareto front may be selected based on specific needs in determining the optimal submarine cable path. Therefore, for routing submarine cables, the present invention provides excellent design flexibility.

### BRIEF DESCRIPTION OF THE DRAWINGS

The patent or application file contains at least one drawing executed in color. Copies of this patent application with color drawing(s) will be provided by the Office upon request and payment of necessary fee.

Embodiments of the invention are described in more details hereinafter with reference to the drawings, in which:

FIG. 1A depicts a process flow diagram illustrating a method for determining optimal submarine cable path for an infrastructure link in accordance with an embodiment of the present invention;

FIG. 1B depicts a process flow diagram for one step of the method in the FIG. 1A;

FIG. 2 depicts a topographic map of a region of the Earth's surface;

FIG. 3 depicts a chart representing an exemplary optimized Pareto front for different safety distances obtained in accordance with an embodiment of the present invention;

FIG. 4A depicts the actual Tonga-Fiji submarine cable path in a contour topographic map of the target region of the Earth's surface;

FIG. 4B depicts the Tonga-Fiji submarine cable path in a map of Peak Ground Velocity (PGV) for the target region in log scale; and

FIG. 5 illustrates three exemplary Pareto optimal submarine cable paths obtained by using a fast-marching method (FMM) in accordance with an embodiment of the present invention.

### DETAILED DESCRIPTION

In the following description, methods and systems for determining optimal submarine cable paths and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

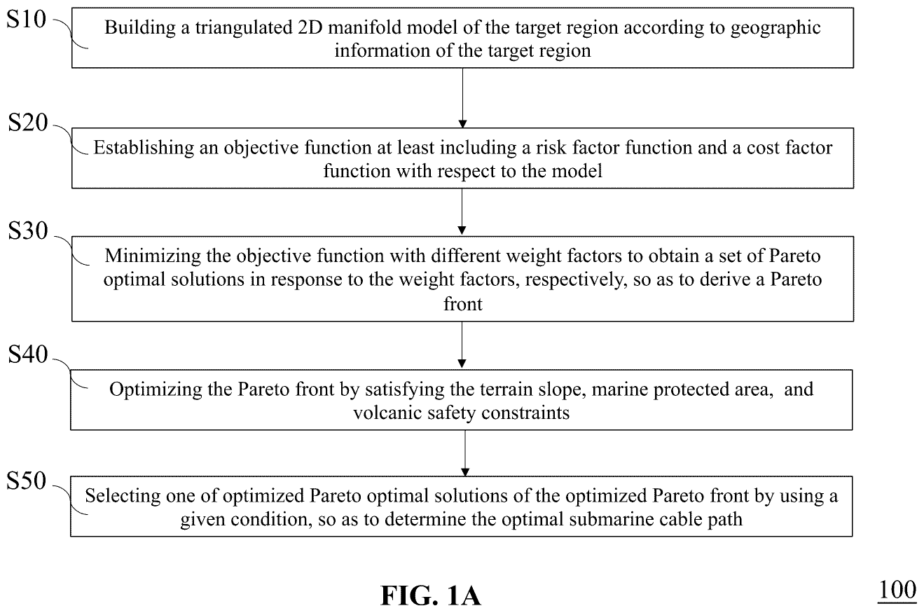

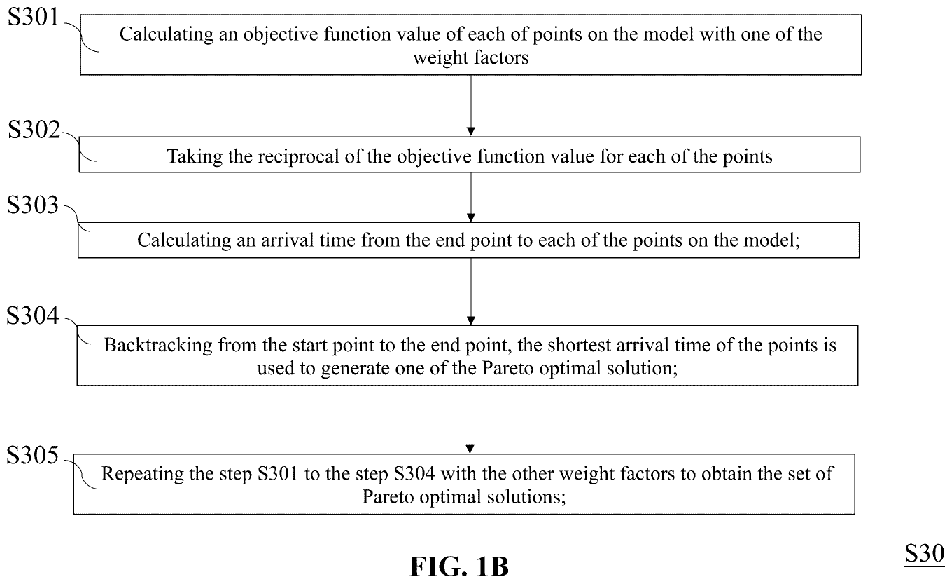

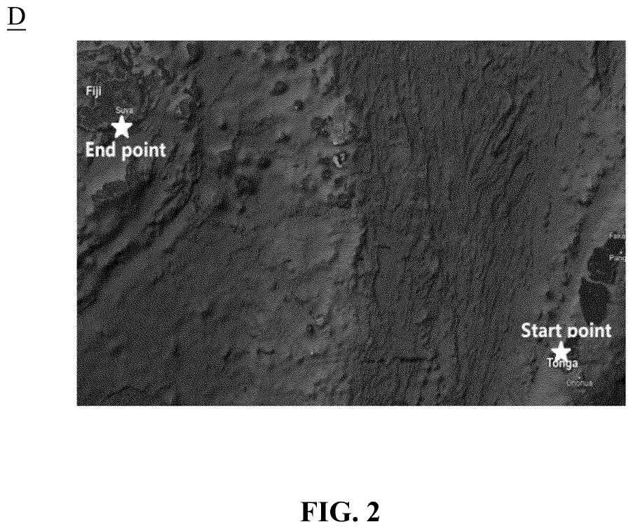

FIG. 1A depicts a process flow diagram illustrating a method 100 for determining an optimal submarine cable path between a starting point and an end point in a target region D of Earth's surface for an infrastructure link in an embodiment of the present disclosure. FIG. 1B depicts a process flow diagram of a step S30 of the method as illustrated in the FIG. 1A. FIG. 2 depicts a topographic map of a target region D of the Earth's surface.

In accordance with one aspect of the present invention, the method 100 includes steps S10 to S50. To illustrate with an example with reference to FIG. 2, the target region D includes two locations: a suburb of Nuku'alofa in Tonga (21°08′31.2″S, 175°13′13.8″W) and Fiji (18°8′43.7″S, 178°28′53.4″E), in which the suburb of Nuku'alofa in Tonga serves as the starting point of a submarine cable path and Fiji serves as the end point of the submarine cable path. The target region D may include other locations, different from Tonga and Fiji, which can also serve as the starting point and the end point.

A. Earth's Surface Model

In step S10, a triangulated two-dimensional (2D) manifold model M of the target region D (as shown in the FIG. 2) is built according to geographic information of the target region D. The triangulated 2D manifold model M in 3D Euclidean space R³ may be built on a state-of-the-art geographic information systems (GIS) for terrain approximation of the target region D, which may represent the model M in a graphical format.

The geographic information of the target region D used in building the model M may include longitude, latitude, elevation, earthquake data, and volcanic data of the target region D. The longitude, latitude, and elevation of the target region D may be obtained from the General Bathymetric Chart of the Oceans (GEBCO, http://www.gebco.net/). The earthquake data and volcanic data of the target region D may be obtained from United States Geological Survey (USGS, https://earthquake.usgs.gov/) and from the Smithsonian Institution's Global Volcanism Program (SIGVP, https://volcano.si.edu/) respectively.

Specifically, the triangulated 2D manifold model M may be represented by a continuous, single-valued function z =ξ(x, y), in which x and y are the latitude and longitude of a point in the model, respectively, and z is the elevation of the point. Geographic terrain of the target region D is modelled, such that each of the points X in the model M is denoted by a 3D coordinate. That is to say, after the aforesaid modelling, any point X in the model M may be expressed as X(x, y, z).

B. Objective Function MF

In step S20, an objective function MF at least including a cost function and a risk function is established with respect to the model M. The cost function and the risk function are fully described as follows.

B1. Cost Function

The cost function represents the consideration of multiple factors affecting cable path planning through a summary cost, which is a sum of the weighted costs of each of the factors. Factors having cost aspects include at least the length of the submarine cable (including the repeaters which are placed every approximately fixed distance along the cable), the location of the submarine cable (with different terrain slope or different ecological/economic values), and the licensing requirements for security arrangements at specific area where the submarine cable is located.

To lay a submarine cable to connect the start point and the end point in the target region D, it is assumed that its cost per unit length at point X(x, y, z) is additive and expressed as c(X). Considering a submarine cable path in the model, the point X on the path with a short arc length s may be written as X=X(s). Let l(p) be the total length of cable path p, the total cost C(p) can be calculated by integrating c(X) from 0 to l(p). The cost function may be written as the following equation (1):

C(p)=∫₀^{L(p)}c(X(s))ds (1)

B2. Risk Function

The risk function represents the potential hazards to the submarine cable path. The factors affecting the risk of damaging or breaking the submarine cable include at least earthquake and seismic sea wave. From another point of view, the risk function represents the number of potential repairs. Specifically, for a given point X(x, y, z) in the model M, it is assumed that the repair rate r(X) of the submarine cable is a non-negative value, and the repair rate r(X) is also additive. Then, the total number of expected or potential repairs of the whole submarine cable R(p) is obtained by integrating r(X) from 0 to l(p). The risk function of a given submarine cable path may be written as the following equation (2):

R(p)=∫∫₀^{L(p)}r(X(s))ds (2)

It should be noted that the repair rate r(X) may be obtained from publicly available information sources and its correlation with ground movement may be found in the context of water and gas pipelines. Many ground motion parameters are used for relating repair rate with seismic intensity. In one embodiment, Peak Ground Velocity (PGV) data, which is a well-represented index reflecting seismic hazard level, is applied to estimate cable repairs associated with earthquakes of a certain point X in the model M. The PGV data can be calculated by historical earthquakes in a region. The PGV data can also be obtained based on Peak Ground Acceleration (PGA) (https://www.usgs.gov/) data provided by United States Geological Survey (USGS, https://earthquake.usgs.gov/).

Next, in accordance with the various embodiments of the present invention, an optimal submarine cable path connecting the start point and end points is designed based on a multi-objective optimization minimizing cost and earthquake risk. In step S20, the objective function MF is established by using the aforesaid risk function R(p) and the cost function C(p).

By considering a given weighted factor w for each of the points X in the model M, the objective function MF representing the weighted sum of cost and risk can be expressed as the following equation (3):

z(X)=c(X)+wr(X) (3)

Then, for a given submarine cable path p, the objective function MF is the total construction cost and the total number of repairs accumulated for the given path. The values of these objective functions are obtained by line integrals over each of given paths. The objective function MF can be expressed as the following equation (4):

Z(p)=C(p)+wR(p)=∫₀^{L(p)}c(X(s))ds+∫₀^{L(p)}r(X(s))ds (4)

where w represents a weight factor.

In step S30, the objective function MF with different weight factors w is minimized to obtain a set of Pareto optimal solutions in response to the weight factors, respectively, so as to derive a Pareto front. The derivation of the Pareto front is described in details in the following paragraphs.

In general, the two objectives in the objective function MF, the cost and the risk are conflicting, so it is impossible to simultaneously minimize both. Therefore, a set of Pareto optimal solutions have to be sought.

To illustrate the obtainment of the set of Pareto optimal solutions with an example with reference to FIG. 2, first, assume the start point and the end point in the FIG. 2 as boundary conditions in the calculation of equation (4). Based on the model M, the boundary conditions, and the objective function MF, the Pareto optimal solution Pₒ for one of the weight factors can be founded by solving the following equation (5):

min_{Po}Z(p)=C(p)+w R(p)=∫₀^{L(p)}c(X(s))ds+∫₀^{L(p)}r(X(s))ds (5)

s.t.Po(A)=X_{A}, Po(B)=X_{B}

Where X_{A} represents the 3D coordinate of the start point in the FIG. 2, and X_{B} represents the 3D coordinate of the end point in the FIG. 2. The step S30 applies a fast-marching method (FMM) to minimize the objective function MF, and it further includes a plurality of sub-steps S301 to S305, which are described as follows.

Referring to FIG. 1B, in sub-step S301, the objective function MF is used to calculate an objective function value of each of points in the model M with one of the weight factors w.

In sub-step S302, the reciprocal of the objective function value for each of the points is taken for converting the minimization into a nonlinear partial differential equation (e.g., the Eikonal equation). The Eikonal equation is a well-known nonlinear partial differential equation that describes the evolution of a front propagating at a constant speed. In the context of submarine cable routing, the Eikonal equation is applied to model the arrival time of a signal from the end point to each point in the model M of the target region D. The reciprocal of the objective function value is taken for each point in the model M, which is then used to convert the minimization into an Eikonal equation.

In sub-step S303, the FMM is applied to solve the Eikonal equation. The computational complexity of FMM is O(N log/V), in which Nis the number of points in the model M. The specific process of applying FMM to solve the Eikonal equation is well known to an ordinarily skilled person in the art.

In sub-step S304, an arrival time from the end point to each of the points in the model M is calculated iteratively until the end point is reached. It should be noted that the solution of the Eikonal equation provides the arrival time from the start point to each point in the model M.

In sub-step S305, backtracking from the start point to the end point, the shortest arrival time of the points is used to generate one of the Pareto optimal solutions.

In sub-step S306, sub-steps S301 to S304 are repeated with the other weight factors, so as to obtain the other Pareto optimal solutions.

After the sub-steps S301 to S306, the set of the Pareto optimal solutions is obtained, and the Pareto front is derived from the Pareto optimal solutions.

The Pareto optimal solutions of the objection function MF represent a trade-off relationship between risk and cost. When making a decision, choosing an optimal scheme needs to balance the trade-off between the two of them. Pareto optimal solutions provide a series of optimal solutions to maximize one goal without sacrificing another. A Pareto front is a collection of all Pareto optimal solutions. Thus, a Pareto front represents the trade-off between risk and cost while the Pareto optimal solutions represent the best solutions among all feasible solutions.

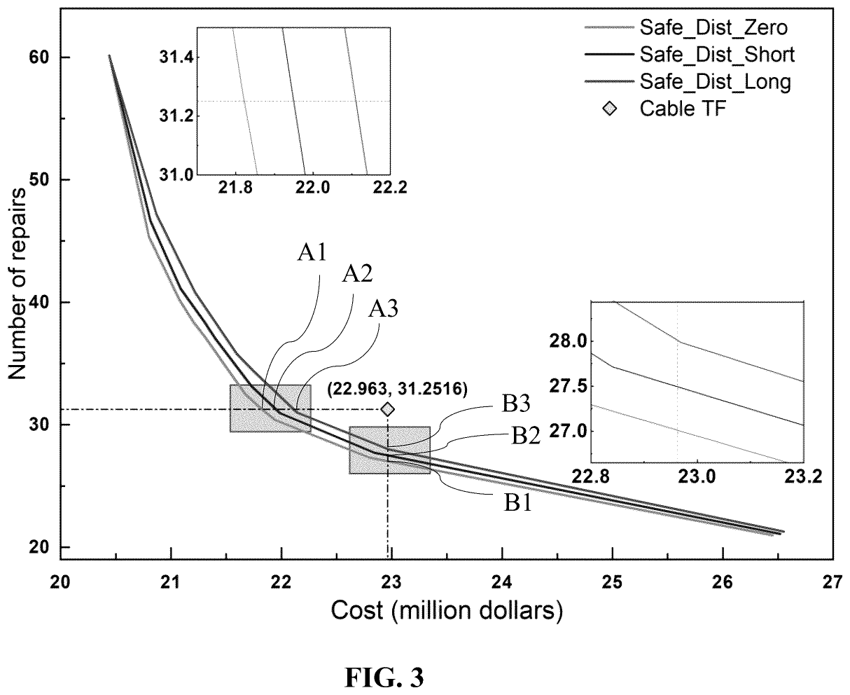

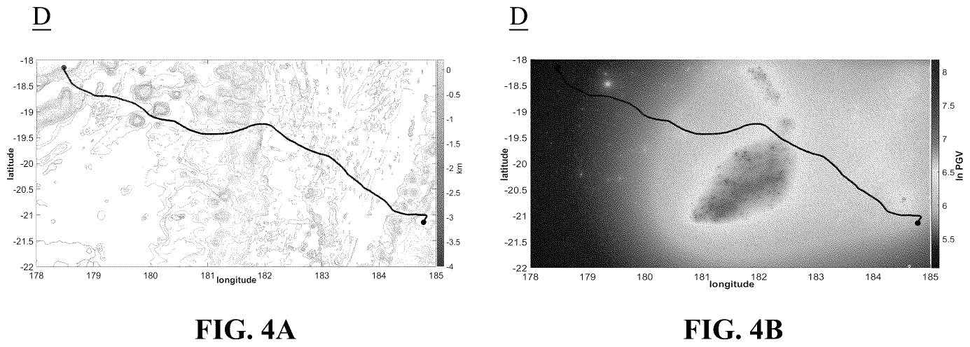

In step S40, the Pareto front is further optimized by satisfying the terrain slope, marine protected area, and volcanic safety constraints. As in the example, the Pareto front is optimized so to avoid potential volcanic risks in the target region D and the high construction costs that may arise from steep slopes, arriving at the optimized Pareto front as represented by the chart shown in the FIG. 3.

After step S40, each of the optimized Pareto optimal solutions of the optimized Pareto front represents a potential optimal submarine cable path. The corresponding potential optimal submarine cable paths satisfy the Terrence slope constraint, such that each is located in a sub-region of the target region where the terrain slope does not exceed approximately 20 degrees. By such constraint, all of the steep regions in the target region D with seabed slopes larger than approximately 20 degrees are avoided, in turn reducing the construction cost of the submarine cable system.

Meanwhile, the potential optimal submarine cable path satisfies the marine protected area constraint, such that the potential optimal submarine cable path is located in a sub-region of the target region D beyond the marine protected areas. In other words, the marine protected areas and the submarine cable installation areas do not overlap with each other. By such constraint, the impact of the submarine cable installation on marine protected areas is minimized.

At the same time, the corresponding potential optimal submarine cable paths also satisfy the volcanic safety constraint, such that the minimum distance between one of the volcanos and the nearest point of the potential submarine cable path in the target region is greater or equal to a volcanic safety distance of the corresponding volcano. That is to say, a potential submarine cable represented by each of the optimized Pareto optimal solutions is not allowed to have any point of its path within a volcanic safety distance of the nearest volcano.

As an example, the optimized Pareto front as represented by the chart shown in the FIG. 3 provides the short volcanic safety distance scenario, the long volcanic safety distance scenario, and zero volcanic safety distance with respect to the volcanic safety constraint.

With respect to the short volcanic safety distance scenario, for example, one of the volcanoes A in the target region D had a volcanic eruption on Jan. 15, 2022, with a VEI level of 5 (which is the highest level in history, denoted as HVEI=5) that caused the real Tonga-Fiji submarine cable to break. The breakpoint of the real Tonga-Fiji submarine cable is about 50 kilometers away from the volcano A. The minimum distance between the volcano A and the nearest point of the corresponding potential submarine cable path is greater or equal to a volcanic safety distance of the corresponding volcano A. In one embodiment, the minimum distance is set to 60 kilometers. For volcanoes B and C in the target region D, the HVEI levels of the volcanoes B and C are 0 and 1 respectively. The volcanic safety distance of the volcano B may be set as, for example, 1 kilometer, and the volcanic safety distance of the volcano C may be set as, for example, 5 kilometers. Therefore, after the Pareto front obtained from the step S30 is optimized by the terrain slope constraint and the short volcanic safety constraint, the optimized Pareto front is obtained and shown as the line denoted as Safe_Dist_Short in FIG. 3.

With respect to the long volcanic safety distance scenario, for example, the volcanic safety distances of the volcanoes A, B, and C are doubled from the ones of the short volcanic safety distance scenario. Therefore, after the Pareto front obtained from the step S30 is optimized by the terrain slope constraint and the long volcanic safety constraint, the optimized Pareto front is obtained and shown as the line denoted as Safe_Dist_Long in FIG. 3.

With respect to the zero volcanic safety distance scenario, for example, the volcanic safety distances of the volcanoes A, B, and C are set to 0, for comparison to the short and long volcanic safety distance scenarios. Therefore, after the Pareto front obtained from the step S30 is optimized by the terrain slope constraint and the zero volcanic safety constraint, the optimized Pareto front is obtained and shown as the line denoted as Safe_Dist_Zero in FIG. 3. In this zero volcanic safety distance scenario, the influence of volcano is ignored.

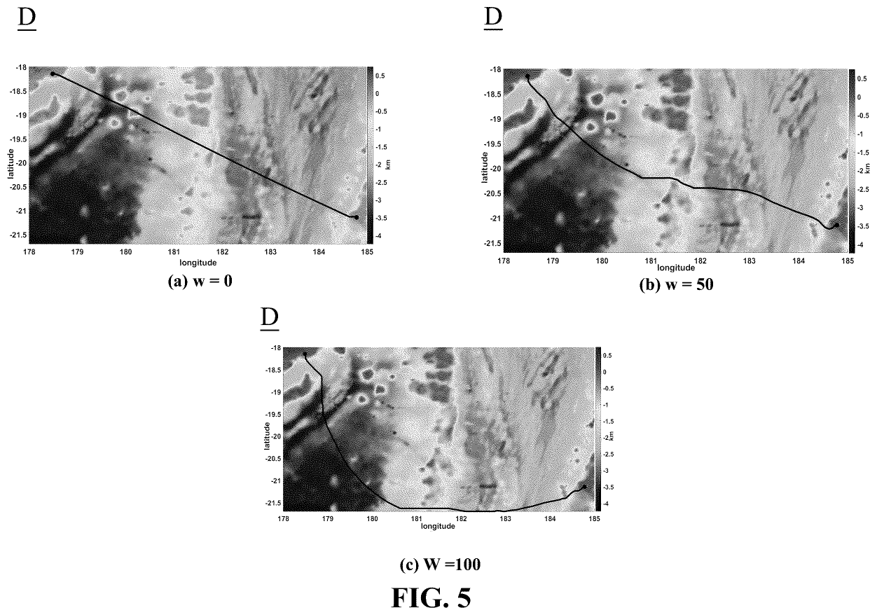

The chart in FIG. 3 also shows the number of repairs and cost of the actual Tonga-Fiji submarine cable TF, which is indicated by the diamond square. Assuming the cost per unit length c(X) at point X(x, y, z) is USD27,000 and the weight factors w are set under the short volcanic safety constraint and the terrain slope constraint, the Pareto optimal cable paths between the same start point and end point of the cable TF are obtained using FMM and the results are shown in Table I as Paths 1-10. Paths 1, 5 and, 6 of the optimized Pareto optimal submarine cable paths are also illustrated in FIG. 5.

TABLE I

| | w | Number of repairs | Total cost (million $) |
|---|---|---|---|
| Cable TF | NA | 31.2516 | 22.963 |
| Path 1 | 0 | 60.0900 | 20.441 |
| Path 2 | 10 | 46.6327 | 20.800 |
| Path 3 | 20 | 41.1199 | 21.077 |
| Path 4 | 30 | 38.3443 | 21.207 |
| Path 5 | 50 | 37.0688 | 21.303 |
| Path 6 | 100 | 33.1604 | 21.671 |
| Path 7 | 150 | 31.6113 | 21.819 |
| Path 8 | 200 | 30.9397 | 21.940 |
| Path 9 | 250 | 27.7164 | 22.797 |
| Path 10 | 300 | 21.0709 | 26.448 |

From the results shown in Table I and FIG. 5, Paths 1-9 of the optimized Pareto optimal submarine cable paths are more cost-effective than the cable TF with lower costs, while Paths 6-10 of the optimized Pareto optimal submarine cable paths have better resilience to risk associated with earthquakes when compared to the cable TF. Path 1, which is shown in part (a) of FIG. 5, is almost a straight line connecting the start point and end point with a minimal cost due to w=0, which means only the cost is considered. The trade-off, however, is that it has to go through earthquake-prone areas with high PGV values. As the w value increases gradually, the path becomes more tortuous in avoiding earthquake-prone areas, as can be seen in parts (b) and (c) of FIG. 5. The result is the increase in length and higher cost.

As can be seen in FIG. 3, the three optimized Pareto optimal solutions, which are denoted as Safe_Dist_Short, Safe_Dist_Long, and Safe_Dist_Zero, are very close to each other. This shows that the optimization under the volcanic safety constraint may not significantly increase the cost of construction, yet allow the protection of the submarine cable from volcanic activities. Moreover, since the number of repairs and cost point of cable TF is above all three optimized Pareto optimal solutions, it implies that the actual submarine cable TF is not a Pareto optimal solution.

In step S50, one of optimized Pareto optimal solutions of the optimized Pareto front is selected based on a given condition, so as to determine the optimal submarine cable path. To illustrate with example with reference to FIG. 5, assuming the given condition is set to the same cost of the cable TF, namely, C_{(Cable TF)}=USD 22.963 million. A horizontal line with a constant cost of 22.963 can be drawn intersecting the optimized Pareto optimal solutions, Safe_Dist_Short, Safe_Dist_Long, and Safe_Dist_Zero, at points A1, A2, and A3 respectively. Extrapolated from points A 1, A2, and A3, the number of repairs for Safe_Dist_Long, Safe_Dist_Short, and Safe_Dist_Zero are 28.0131, 27.4957, and 27.0166 respectively. These numbers are lower than that of the cable TF by 10.36%, 12.02%, and 13.55% respectively. Each of the points A1, A2, and A3 represents the corresponding Pareto optimal solution under the corresponding terrain constraint and the volcanic safety distance constraint. Thus, a corresponding optimal submarine cable may be determined from point A1, A2, or A3.

To further illustrate with another example with reference to FIG. 5, assuming the given condition is set to the same number of repairs for the cable TF, namely, R_{(Cable TF)}=31.2516. A vertical line with a constant number of repairs of 63.1476 can be drawn intersecting the optimized Pareto optimal solutions, Safe_Dist_Short, Safe_Dist_Long, and Safe_Dist_Zero, at points B1, B2, and B3 respectively. Extrapolated from points B1, B2, and B3, the costs of Safe_Dist_Long, Safe_Dist_Short, and Safe_Dist_Zero are USD 22.1176, 21.9503, and 21.8251 million respectively. These numbers represent the cost savings of 3.68%, 4.41%, and 4.96% respectively when compared to that of the cable TF. Each of the points B1, B2, and B3 represents the corresponding Pareto optimal solution under the corresponding terrain constraint and the volcanic safety distance constraint. Thus, a corresponding optimal submarine cable may be determined from point B1, B2, or B3.

Based on above, in accordance with the embodiments of the present invention, the FMM-based method and system for automatic submarine cable path routing are proposed. The FMM-based method and system fully consider the historical data on earthquakes and volcano eruptions with different VEI levels to obtain the optimized Pareto optimal submarine cable paths. In practice, the optimized Pareto optimal submarine cable paths may serve as references for comparison and benchmarking for submarine cable path planners in their path planning.

Under certain circumstances, a submarine cable planner can be presented with the costs of the cable system construction under multiple alternatives, each associated with a different volcanic safety distance. If, for example, the optimal submarine cable path planning in the case of the longest volcanic safety distance costs only 3% more than that in the case of zero volcanic safety distance, then the submarine cable planner may decide to pay the extra 3% to achieve resilience against anticipated volcanic eruptions. Thus, submarine cable path planners can choose the level of safety distance based on cost consideration.

The functional units and modules of the system, method and/or non-transitory computer readable medium in accordance with the embodiments disclosed herein may be implemented using computing devices, computer processors, or electronic circuitries including but not limited to application specific integrated circuits (ASIC), field programmable gate arrays (FPGA), microcontrollers, and other programmable logic devices configured or programmed according to the teachings of the present disclosure. Computer instructions or software codes running in the computing devices, computer processors, or programmable logic devices can readily be prepared by practitioners skilled in the software or electronic art based on the teachings of the present disclosure.

All or portions of the methods in accordance to the embodiments may be executed in one or more computing devices including server computers, personal computers, laptop computers, mobile computing devices such as smartphones and tablet computers.

The embodiments may include computer storage media, transient and non-transient memory devices having computer instructions or software codes stored therein, which can be used to program or configure the computing devices, computer processors, or electronic circuitries to perform any of the processes of the present invention. The storage media, transient and non-transient memory devices can include, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

Each of the functional units and modules in accordance with various embodiments also may be implemented in distributed computing environments and/or Cloud computing environments, wherein the whole or portions of machine instructions are executed in distributed fashion by one or more processing devices interconnected by a communication network, such as an intranet, Wide Area Network (WAN), Local Area Network (LAN), the Internet, and other forms of data transmission medium.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

What is claimed is:

1. A method of determining an optimal submarine cable path between a starting point and an end point in a target region of Earth's surface, comprising:
building a triangulated two-dimensional (2D) manifold model of the target region according to a geographic information of the target region;
establishing an objective function at least including a risk function and a cost function with respect to the established model; and
minimizing the objective function with different weight factors to obtain a set of Pareto optimal solutions in response to the weight factors, respectively, so as to derive a Pareto front;
optimizing the Pareto front by satisfying terrain slope, marine protected area, and volcanic safety constraints, so as to obtain an optimized Pareto front; and
selecting one of optimized Pareto optimal solution of the optimized Pareto front by using a given condition, so as to determine the optimal submarine cable path.

2. The method of claim 1, wherein geographic terrain of the target region is modelled, such that each of the points in the model is denoted by a three-dimensional (3D) coordinate.

3. The method of claim 1, wherein the cost function is at least determined by at least one of factors including length of the submarine cable, location of the submarine cable, and requirements or licensing for security arrangements at specific areas where the submarine cable is located.

4. The method of claim 1, wherein the risk function is at least determined by a PGV data of the target region.

5. The method of claim 1, wherein the objective function is established by using the cost function and the risk function.

6. The method of claim 1, wherein the objective function is expressed as the following equation:
Z(p)=C(p)+wR(p);
wherein p represents a submarine cable path, Z(p) represents the objective function, R(p) represents the risk function, and w represents the weight factor.

7. The method of claim 1, wherein the step of minimizing the objective function further comprising:
applying a fast-marching method (FMM) to minimize the objective function with the different factors to obtain the set of Pareto optimal solutions.

8. The method of claim 7, wherein the step of applying the FMM further comprises:
step A: using the objective function to calculate an objective function value of each of points in the model with one of the weight factors;
step B: taking the reciprocal of the objective function value for each of the points for converting the minimization into an Eikonal equation;
step C: applying the FMM to solve the Eikonal equation;
step D: calculating an arrival time from the end point to each of the points in the model iteratively until reaching the end point;
step E: backtracking from the start point to the end point and using the shortest arrival time of the points to generate one of the Pareto optimal solutions; and
step F: repeating the step A to the step E with the other weight factors, so as to obtain the set of Pareto optimal solutions.

9. The method of claim 1, wherein after the step of optimizing the Pareto front, each of the optimized Pareto optimal solutions of the optimized Pareto front represents a potential optimal submarine cable path,
wherein the potential optimal submarine cable path satisfies the Terrence slope constraint, such that the potential optimal submarine cable path is located in a sub-region of the target region where the terrain slope does not exceed approximately 20 degrees.

10. The method of claim 1, wherein after the step of optimizing the Pareto front, each of the optimized Pareto optimal solutions of the optimized the Pareto front represents a potential optimal submarine cable path,
wherein the potential optimal submarine cable path satisfies the volcanic safety constraint, such that the minimum distance between one of the volcanos and the nearest point of the potential submarine cable path is greater or equal to a volcanic safety distance of the corresponding volcano.

11. The method of claim 10, wherein the volcanic safety distance is determined by highest historical volcanic explosivity index (HEVI) of the corresponding volcano in the target region.

12. The method of claim 10, wherein after the step of optimizing the Pareto front, each of the optimized Pareto optimal solutions of the optimized Pareto front represents a potential optimal submarine cable path,
wherein the potential optimal submarine cable path satisfies the marine protected area constraint, such that the potential optimal submarine cable path is located in a sub-region of the target region where is beyond marine protected areas of the target region.

13. The method of claim 1, wherein the given condition comprises a constant risk or a constant cost.

14. The method of claim 1, wherein the geographic information of the target region comprises longitude, latitude, elevation, earthquake data and volcano data of the target region.

15. A system for determining an optimal submarine cable path between a starting point and an end point in a target region of Earth's surface, comprising:
one or more processors arranged to:
building a triangulated two-dimensional (2D) manifold model of the target region according to a geographic information of the target region;
establishing an objective function at least including a risk function and a cost function with respect to the model; and
minimizing the objective function with different weight factors to obtain a set of Pareto optimal solutions in response to the weight factors, respectively, so as to derive a Pareto front;
optimizing the Pareto front by satisfying terrain slope, marine protected area, and volcanic safety constraints, so as to obtain an optimized Pareto front; and
selecting one of optimized Pareto optimal solution of the optimized Pareto front by using a given condition, so as to determine the optimal submarine cable path; and
a display arranged to display the determined optimal submarine cable path.

16. A non-transitory computer readable medium for storing computer instructions that, when executed by one or more processors, causes the one or more processors to perform a method for determining an optimal submarine cable path between a starting point and an end point in a target region of Earth's surface, comprising:
building a triangulated two-dimensional (2D) manifold model of the target region according to a geographic information of the target region;
establishing an objective function at least including a risk function and a cost function with respect to the model; and
minimizing the objective function with different weight factors to obtain a set of Pareto optimal solutions in response to the weight factors, respectively, so as to derive a Pareto front;
optimizing the Pareto front by satisfying terrain slope, marine protected area, and volcanic safety constraints, so as to obtain an optimized Pareto front; and
selecting one of optimized Pareto optimal solution of the optimized Pareto front by using a given condition, so as to determine the optimal submarine cable path.
